(19) United States
(12) Patent Application Publication
(10) Pub. No.: US 2025/0021731 A1
(43) Pub. Date: Jan. 16, 2025

(54) OPTIMIZED WEIR PLATE DESIGN USING GENETIC ALGORITHMS TO PROTECT CRITICAL RESOURCES

(71) Applicant: Marcus Quigley, Brookline, MA (US)

(72) Inventor: Marcus Quigley, Brookline, MA (US)

(21) Appl. No.: 18/896,894

(22) Filed: Sep. 26, 2024

(51) Int. Cl. G06F 30/28; G06F 30/27

(52) U.S. Cl. CPC G06F 30/28; G06F 30/27

(57) ABSTRACT

An optimized weir plate design method uses genetic algorithms to design an optimal outlet design to regulate pond outflows, protecting critical habitats during development projects. The method involves collecting hydrological data, defining a target flow-duration curve, generating weir plate designs with varying orifice sizes and positions, simulating pond routing, and evaluating fitness based on the mean squared error between simulated and target flow-duration curves. Genetic algorithm operations evolve the designs toward optimization. The optimized designs are visualized and are suitable for manufacturing using laser-cut aluminum plates, offering a cost-effective and practical solution for sustainable development and environmental conservation.

### PRIOR ART

Existing stormwater management practices often utilize detention ponds with weirs risers, controlled or uncontrolled valves, and other designed hydraulic structures to regulate outflow rates. Traditional designs typically focus on peak flow reduction and water quality performance but lack precision in maintaining natural hydrological regimes necessary for critical habitats. Current methods for designing outlet structures are limited and do not adequately address the complexities involved in balancing development needs with environmental conservation and specifically preserving or restoring pre-development flow-duration characteristics.

Various methods and systems have been developed for designing weir plates and regulating pond outflows in stormwater management. Traditional weir plate designs often utilize fixed configurations with standard orifices, which may not account for site-specific hydrological conditions or ecological sensitivities.

U.S. Pat. No. 5,342,144 (Mccarthy), “Stormwater Control System” discloses a system and method for controlling stormwater discharge using a flow control device with an adjustable orifice. The device allows for the regulation of outflow rates by manually adjusting the size of the orifice opening to accommodate different stormwater volumes. While this invention provides a means to control discharge rates, it relies on manual adjustments and does not incorporate computational optimization to achieve precise outflow characteristics that match target flow-duration curves necessary for protecting critical habitats.

The adjustable orifice in U.S. Pat. No. 5,342,144 is designed to be modified in response to observed conditions or anticipated storm events. However, this manual approach can be labor-intensive and may not respond effectively to the dynamic and complex hydrological patterns associated with critical habitats. Additionally, the patent does not address the use of genetic algorithms or any automated optimization techniques to design the orifice configurations.

In contrast, the present invention employs genetic algorithms to optimize weir plate designs by adjusting orifice sizes and positions computationally. This method produces outflow hydrographs that closely match a predefined target flow-duration curve, ensuring that the outflow mimics natural hydrological regimes essential for the preservation of sensitive ecosystems.

Furthermore, U.S. Pat. No. 5,342,144 does not provide a mechanism for visualizing the optimized weir plate design to facilitate practical implementation and manufacturing. The present invention addresses this gap by generating visual representations of the optimized designs, making them suitable for manufacturing using methods like laser-cutting of aluminum plates.

Therefore, while U.S. Pat. No. 5,342,144 contributes to the field of stormwater management by providing an adjustable flow control device, it does not teach or suggest the automated optimization of weir plate designs using genetic algorithms to achieve target flow-duration curves. The present invention advances the state of the art by integrating computational optimization techniques with practical manufacturing considerations to protect critical habitats effectively during new development projects using passive weir designs.

U.S. Pat. No. 10,831,164 B2 (Goodman and Quigley), “Optimized hydromodification management with active stormwater controls” discloses a system and method for optimizing stormwater management using automated control mechanisms. This patent describes an intelligent stormwater control system that utilizes sensors and real-time data to adjust flow control devices dynamically. The system aims to improve flood mitigation and water quality by responding to changing environmental conditions.

The invention in U.S. Pat. No. 10,831,164 B2 focuses on active control of stormwater infrastructure through the integration of hardware components such as sensors, actuators, and controllers. It employs algorithms to process real-time data and make decisions on adjusting valves or gates to regulate water flow. While this approach enhances adaptability and responsiveness, it relies on complex mechanical systems and continuous data input, which may increase costs and maintenance requirements.

In contrast, the present invention employs genetic algorithms to optimize weir plate designs in a passive system without the need for active mechanical components or real-time data inputs. By computationally adjusting orifice sizes and positions, the method produces outflow hydrographs that closely match target flow-duration curves necessary for protecting critical habitats. This optimization is performed prior to installation, resulting in a static weir plate design that consistently regulates outflow based on pre-defined parameters.

Furthermore, U.S. Pat. No. 10,831,164 B2 does not teach or suggest the use of genetic algorithms for optimizing the physical design of weir plates to achieve specific hydrological outcomes. It also does not address the practical implementation of such optimized designs using manufacturing methods like laser-cut aluminum plates, nor does it provide visual representations to facilitate manufacturing and stakeholder communication.

Therefore, while U.S. Pat. No. 10,831,164 B2 contributes to the field of stormwater management by introducing active control systems with real-time responsiveness, it does not anticipate or render obvious the present invention's method of using genetic algorithms to optimize weir plate designs for passive, ecologically sensitive stormwater regulation. The present invention advances the state of the art by providing a cost-effective, low-maintenance solution that integrates advanced computational optimization with practical manufacturing considerations to protect critical habitats effectively during new development projects.

### BACKGROUND OF THE INVENTION

Critical habitats such as wetlands, streams, and estuaries provide essential ecological services, including biodiversity support, water purification, and flood control. Development activities near these areas can disrupt natural hydrological regimes, leading to adverse ecological effects like erosion, habitat loss, and decreased water quality.

There is a need for an innovative method that optimizes outlet structure weir plate designs to achieve desired outflow characteristics, aligning with environmental objectives while being practical for implementation. Utilizing genetic algorithms offers a robust optimization technique capable of navigating large and complex search spaces to find near-optimal solutions for weir plate configurations.

### SUMMARY OF THE INVENTION

The present invention provides a method and system for optimizing weir plate designs using genetic algorithms to produce outflow hydrographs that closely match a target flow-duration curve (FDC). By integrating hydrological data and simulating pond routing, the method adjusts orifice configurations on the weir plate to achieve desired outflow characteristics, thereby protecting critical habitats following the development of upstream sites.

The method involves collecting hydrological data, defining a target FDC, generating an initial population of weir plate designs, simulating pond routing, evaluating fitness using a genetic algorithm, and evolving designs toward optimization. The optimized weir plate designs are visualized to facilitate practical implementation and are conducive to manufacturing using laser-cut aluminum plates.

This approach enhances sustainable development by optimizing pond sizing and ensuring compliance with ecological requirements, offering a cost-effective and practical solution for developers and environmental managers.

### BRIEF DESCRIPTION OF DRAWINGS

FIG. 1 illustrates a flowchart of the optimization method for weir plate design using genetic algorithms.

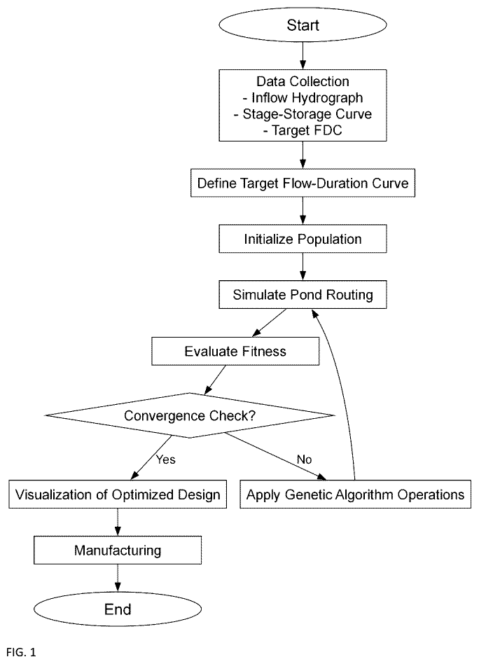

FIG. 2 depicts a diagram of one examples of an infinite number of potential optimized weir plate designs showing orifice sizes and positions.

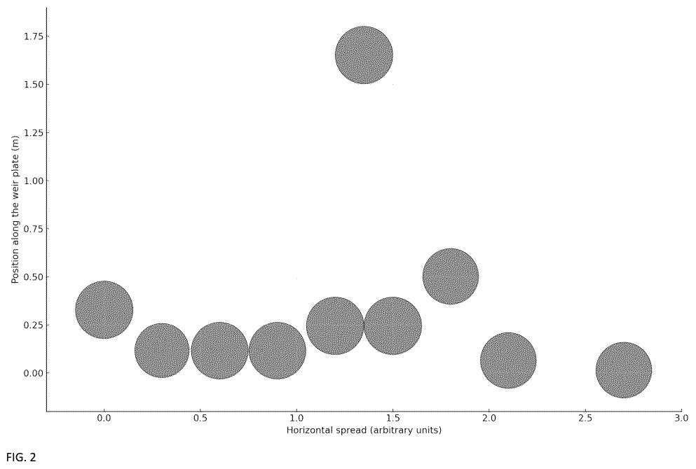

### DETAILED DESCRIPTION OF THE INVENTION

The invention presents a method for optimizing weir plate designs in detention ponds using genetic algorithms to protect critical habitats during new development projects. By adjusting the size and placement of orifices on weir plates, the method aims to produce outflow patterns that closely match target flow-duration curves representative of natural conditions.

### Methodology

Data Collection-Essential hydrological data are collected:
Inflow Hydrograph: A time series of inflow rates over a significant period (e.g., 25 years) to capture runoff variability.
Stage-Storage Curve: A relationship between water level (stage) and storage volume in the pond.
Target Flow-Duration Curve: A desired FDC representing the outflow characteristics needed to protect critical habitats.

### Defining the Target Flow-Duration Curve

The target FDC is established based on pre-development flow patterns, ecological requirements, or regulatory standards. It serves as the benchmark for evaluating the performance of weir plate designs.

### Initialization of Population

An initial population of weir plate designs is generated, with each individual representing a unique configuration of orifices characterized by their sizes and positions within specified ranges:
Orifice Sizes: Diameters ranging from 0.05 to 0.5 meters.
Orifice Positions: Elevations ranging from 0.0 to 2.0 meters on the weir plate.

Constraints are applied to ensure practical feasibility and regulatory compliance.

### Pond Routing Simulation

For each weir plate design, the pond's response to the inflow hydrograph is simulated using the stage-storage curve. The outflow through each orifice is calculated based on the orifice flow equation:

$$Q = {C}_{d} \cdot A \cdot \sqrt{2 \cdot g \cdot h}$$

Where:
Q=flow rate through the orifice.
C_{d}=discharge coefficient (typically 0.6).
A=orifice area.
g=gravitational acceleration (9.81 m/s²).
h=hydraulic head (stage minus orifice elevation).

### Fitness Evaluation

The simulated outflow hydrograph is converted into a flow-duration curve. The fitness of each weir plate design is evaluated by calculating the mean squared error (MSE) between the simulated FDC and the target FDC:

$$M S E = \frac{1}{n} {\sum }_{i = 1}^{n} {( {Q}_{simulated , i} - {Q}_{target , i} )}^{2}$$

Designs with lower MSE values are considered fitter.

### Genetic Algorithm Operations

The genetic algorithm evolves the population through:
Selection: Fitter individuals are selected based on fitness scores.
Crossover: Orifice configurations are exchanged between parent designs to create offspring.
Mutation: Random changes are introduced by adding, removing, or modifying orifices.

This process repeats over multiple generations until convergence criteria are met.

### Visualization of Optimized Design

A visual representation of the optimized weir plate design is generated, showing:
Orifice Sizes and Positions: Depicted on the weir plate diagram.
Weir Plate Dimensions: Providing context for the design.

This aids in communication among stakeholders and guides the manufacturing process.

### Manufacturing Feasibility

The optimized weir plate designs are suitable for manufacturing using laser-cut aluminum plates due to:
Precision: Accurate reproduction of specified orifice sizes and positions.
Efficiency: Reduced fabrication time and labor costs.
Durability: Aluminum provides corrosion resistance and structural integrity.

### Advantages of the Invention

The invention offers several benefits:
Environmental Protection: Maintains natural flow regimes to protect critical habitats.
Optimization: Efficiently achieves desired outflow characteristics.
Cost-Effectiveness: Optimizes pond size and outlet structures, reducing costs.
Manufacturing Ease: Simplifies production using standard materials and methods.
Regulatory Compliance: Facilitates adherence to environmental regulations.

1. A method for optimizing weir plate designs to regulate pond outflows by collecting hydrological data, defining a target flow-duration curve, generating an initial population of weir plate designs, simulating pond routing, evaluating the fitness of designs by comparing simulated outflow hydrographs to the target curve, applying genetic algorithm operations including selection, crossover, and mutation to evolve the population, generating visual representations of optimized designs, and facilitating manufacturing using laser-cut aluminum plates.

2. The method of claim 1, wherein the fitness evaluation uses mean squared error between the simulated and target flow-duration curves.

3. The method of claim 1, further comprising incorporating constraints on orifice sizes and positions to ensure compliance with regulatory standards and practical feasibility.

4. A system for optimizing weir plate designs to regulate pond outflows, comprising a data processing unit configured to execute the method of one of claims 1 to 3, input interfaces for receiving hydrological data and design parameters, and output interfaces for providing optimized weir plate designs and visual representations.

5. A method according to claim 1, wherein the weir plate designs further comprise slots or cut-out shapes that are hydraulically equivalent to the orifice configurations, wherein said slots or cut-out shapes are selected based on their ability to achieve hydrographs that match the target flow-duration curve.

6. A method according to claim 1, wherein the optimized weir plate designs are manufactured using techniques selected from the group consisting of water jet cutting, CNC milling, die casting, and 3D printing, each technique being suitable for producing the specified orifice sizes and positions in materials including but not limited to aluminum, steel, and plastics.
